(19) United States
(12) Patent Application Publication
(10) Pub. No.: US 2007/0134595 A1
(43) Pub. Date: Jun. 14, 2007

(54) Pressurized aerosol formulation for use in radiation sensitive coatings

(75) Inventor: Harris Miller, Sharon, MA (US)

Correspondence Address: WIGGIN AND DANA LLP;ATTENTION: PATENT DOCKETING, ONE CENTURY TOWER, P.O. BOX 1832, NEW HAVEN, CT, 06508-1832, US

(73) Assignee: MicroChem Corp.

(21) Appl. No.: 11/633,313

(22) Filed: Dec. 4, 2006

Related U.S. Application Data
(60) Provisional application No. 60/748,812, filed on Dec. 8, 2005.

(51) Int. Cl. G03F 7/00; G03C 5/00; B67D 5/30

(52) U.S. Cl. 430/300; 430/311; 222/14

(57) ABSTRACT

The present invention is directed to a coating composition, comprising a photoresist composition; and a propellant miscible in the photoresist composition, as well as a pressurized container, comprising a coating composition contained in the pressurized container and comprising a photoresist composition; and a propellant miscible in the photoresist composition; and a valve capable of forming an aerosol spray of the coating composition when activated; wherein the pressurized container has a pressure of greater than 1 atm.

### CROSS-REFERENCE TO RELATED APPLICATIONS

This application claims the benefit of U.S. Provisional Patent Application Ser. No. 60/748,812 filed Dec. 8, 2005.

### BACKGROUND OF THE INVENTION

1. Field of the Invention

The present invention relates to a pressurized aerosol spray composition consisting of a liquid photoresist and propellant contained in an aerosol spray can in which the composition may be emitted through an atomization valve for use in producing aerosol spray-coatings of photoresist. Specifically, this invention consists of a single-phase, miscible mixture of photoresist and propellant in a pressurized spray container, for use in delivering the aerosol mixture onto substrates for producing microelectronics, micromechanical, microelectronic, microfluidic, electrophoretic devices and other three-dimensional imaging applications.

2. Brief Description of Art

Aerosol propellant compositions have found broad-based acceptance in many commercial applications, such as; cosmetics, medicine, food and insecticides. Numerous self-propelling aerosol spray systems are already known, such as U.S. Pat. No. 3,387,425, which describes a spray can filled with a liquid concentrate, and which the spray can is enclosed with a valve and filled with a propellant to produce a saturated solution of concentrate and compressed gas. Common propellant gases for aerosol spray systems can be chlorofluorinated saturated aliphatic hydrocarbons, such as; dichlorodifluoromethane, trichloromonofluoromethane, dichlorotetrafluoroethane and mixtures thereof. Such chlorofluorocarbon propellants, also known as CFCs, once released into the atmosphere, have been known to create unwanted greenhouse effects and thereby pollute the environment.

U.S. Pat. No. 4,134,968 describes an aerosol, which contains a liquid mixture of hydrocarbon, propellant, water and organic solvent, in which the liquid mixture forms a single-phase. Examples of such hydrocarbon propellants are dimethoxymethane, ethyl acetate, acetone, dimethyl ether (U.S. Pat. No. 4,543,202), diethyl ether, 2-methoxyethanol, 2-ethoxyethanol or butanol. Other propellant gases have been found to replace CFCs and hydrocarbon propellants, by replacing the propellant gas with carbon dioxide (CO₂), nitrogen (N₂)or air. However, these propellant gases do not produce a miscible mixture with the photoresist, depending on the propellant gas pressure, nor are they capable of providing the aerosol can with a ballast or reserve of propellant gas. Such gas ballasts or reserves are derived from a propellant which is a liquid or a solid under pressure and are capable of generating more gaseous propellant by a phase change to the gaseous state which is induced either by changes in pressure or by direct sublimation.

Although aerosol propellant compositions are prevalent in cosmetics, medicine, food, paints and insecticides, almost no commercial applications of aerosol propellant compositions for imaging or photo-induced systems can be found. This is mainly because of the constraints on coating uniformity that imaging systems demand. By far, the most common method for coating micron-thick coatings to produce micron-sized devices is a technique known as spin-coating, which suffices for most flat, circular objects; but does not lend itself to irregular, square, rectangular or three-dimensional substrates. Because imaging systems produce features that are micron-sized, small changes in coating uniformity produce unacceptable variations in image quality, rendering spray-coatings unusable for many applications. For these reasons, it has been accepted that spray coatings could not produce sufficient coating uniformity to render the coating useful for imaging systems requiring micron-size features.

A photopositive resist aerosol propellant composition is available from CRC Industries (Zele, Belgium) and sold under the tradename “POSITIV 20”. This product is a low-resolution, positive photoresist in a spray can designed for low volume production of printed circuit boards. These photosensitive PCB plates are usually copper-clad, fiberglass boards, which have been coated with a photosensitive material using coating techniques such as slot, slit, web or other cascading systems. Typically PCBs have millimeter-sized copper features and are incapable of producing micron-sized features. Therefore, based on the limited coating uniformity attainable by common aerosol spray systems, such a product is believed not to be appropriate for production of micron-sized features on the PCB.

It is also known to incorporate a photoresist composition into a mechanical spray system in which a continuous supply of gaseous propellant feeds a vessel containing photoresist. Such non-portable, fixed-mechanical systems commonly use gaseous nitrogen under constant pressure in combination with an ultrasonic or piezoelectric induced nozzle. The mechanical spray systems taught by U.S. Pat. No. 5,543,265 (Garza); U.S. Pat. No. 5,554,486 (Garza); U.S. Pat. No. 6,302,960 (Baroudi et al.); and U.S. Pat. No. 6,596,988 (Corso et al.) consist of an inhomogenous mixture of nitrogen gas and photoresist composition in a pressurized vessel.

### BRIEF SUMMARY OF THE INVENTION

In one aspect, the present invention is directed to a coating composition, comprising a photoresist composition; and a propellant miscible in the photoresist composition.

In another aspect, the present invention is directed to a pressurized container, comprising a coating composition contained in the pressurized container and comprising a photoresist composition; and a propellant miscible in the photoresist composition; and a valve capable of forming an aerosol spray of the coating composition when activated; wherein the pressurized container has a pressure of greater than 1 atm.

In another aspect, the present invention is directed to a pressurized container, comprising a first chamber comprising a valve capable of forming an aerosol spray and containing a coating composition comprising a photoresist composition; and a second chamber adjacent to the first chamber and applying pressure to the first chamber.

### DETAILED DESCRIPTION OF THE INVENTION

The present invention is directed to miscible, single-phase pressurized aerosol mixtures useful for applying a photoresist composition to a substrate. The present invention is also directed to a pressured container containing a miscible, single phase photoresist composition and a propellant, where the container contains a valve capable of forming a ballistic aerosol spray of the photoresist which may be applied to a substrate. In an alternative embodiment, the pressurized container may include a pressurized chamber that applies pressure to the composition of the invention so that it is not necessary to implement a separate propellant that is miscible with the photoresist compositions.

An advantage of the present invention involves a solution to the problem of applying a photoresist composition to a substrate when the conventional method of spin-coating photoresists fails to produce a smooth and even coating. Such is the case for devices having significant surface topography greater than a few microns or other features with high aspect ratios, where aspect ratio is defined by the ratio of the height of the object to the width or diameter. The present invention is also advantageous when the substrate is perforated or contains voids which prevent a spin-coating altogether because the perforations or voids do not allow the spin-coater to hold the substrate by vacuum during spin-coating. The present invention is also advantageous when more than one side of a substrate needs to be patterned with photoresist and as such the first side also cannot make contact with a flat surface or vacuum chuck for a spin-coater. The present invention also offers advantages when there is a need to coat and pattern a three dimensional surface.

Producing aerosol propellant compositions for imaging micron-sized features in thin, micron thick coatings require careful selection of the propellant, polymer, photoactive compound, solvent, leveling compound, valve seal, actuator and can lining. The simple combination of a photoresist and a propellant is insufficient for producing a consistent and stable, radiation sensitive aerosol propellant composition for micron-size features for many micron-based imaging systems. The present inventor has unexpectedly discovered that it is the superadditive combination of these components which produces a high-resolution, stable composition.

A single-phase, homogeneous mixture is critical to performance of a high-resolution photoresist aerosol propellant composition. Without such a mixture, a uniform ballistic spray cannot be produced and a uniform micron thick coating cannot be obtained. The need for a homogenous mixture can, however be obviated, in the event that a two-component aerosol container is used.

As defined herein, the phrase “radiation-sensitive” refers to compositions which become more or less soluble in a solvent upon exposure to radiation. The phrase “positive-acting photoresist composition” refers to a photoresist where areas that have been exposed to light or ultra violet (UV) radiation are eventually removed from the applied photoresist coating or layer after exposure and by subsequent treatments such as with a developing solution containing either an aqueous alkali solution, ammonia gas, or organic solvent and the unexposed areas remain. The phrase “negative-acting photoresist composition” refers to a photoresist where areas that are exposed to radiation remain insoluble after exposure and during subsequent treatment while areas not subject to exposure are removed during subsequent treatments. The term “photoresist composition” as used in the present specification and claims is defined as a composition that includes at least one polymer component, a photosensitive component, and a solvent component. Such photoresist compositions may also contain other optional components such as surfactants, plasticizers, dyes photoinitiators, and other conventional photoresist additives.

As indicated above, the present invention is directed to a coating composition, comprising a photoresist composition and a propellant miscible in the photoresist composition; wherein the coating composition is contained in a container having an internal pressure of greater than 1 atm, and wherein the coating composition forms a ballistic aerosol spray when applied to a substrate. Each of these components is discussed in more detail below.

Negative-acting photoresist compositions comprise primarily a polymer component, a photosensitive component, a crosslinking agent, and a solvent component. One preferred composition for negative-acting photoresists is a mixture of novolak polymers and a glycouril cross-linking compound. One preferred photosensitive component for negative-acting photoresists is a hexafluoroantimonate salt. The solvent component may include any conventional photoresist solvents, such as cyclopentanone, propylene glycol monomethyl ether acetate, ethyl lactate, acetone and the like. The amount of such components is not a critical feature of the present invention.

One preferred photoresist is negative-acting photoresists such as n-LOR and MicroSpray Negative photoresists available from MicroChem Corp. (Newton, Mass.). Another preferred polymer component for negative-acting photoresists consists of a mixture of a self-cross-linking polymer, such as a bisphenol A-based “Epon Resin”, which does not require a separate cross-linking compound. In this case, only the Epon Resin, photoactive compound, surfactant and solvent are present in the photoresist. Examples of such bisphenol A-based resins include SU-8 MicroSpray, SU-8, SU-8 2000, SU-8 3000 or SU-8 4000 available from MicroChem Corp. (Newton, Mass.).

One preferred polymer component for positive-acting photoresist is a mixture of novolak resins, a photosensitive component such as diazonaphthoquinone sulfonate, solvent and surfactant. The amount of such components is not a critical feature of the present invention.

One preferred positive-acting photoresist is known as Rohm & Haas S1800 and is available from MicroChem Corp. (Newton, Mass.). Another preferred positive-acting photopolymer, sensitive to deep ultra-violet radiation between 240-290 nm, e-beam and x-ray radiation is known as polydimethyl-glutarimide and is available as PMGI or LOR™ from MicroChem Corp. (Newton, Mass.).

Any suitable propellant which is miscible and forms a single phase homogeneous solution with the photoresist composition may be used in the coating composition of the invention. Preferred propellants are hydrocarbon propellants. Examples of suitable propellants include dimethoxymethane, ethyl acetone, acetone, dimethyl ether, 2-methoxyethanol, 2-ethoxyethanol or butanol. Most preferred is dimethyl ether, however azeotropic mixtures of these and other propellants with CO₂, N₂ or air may also be used.

Another suitable propellant, known as 1,1,1,2-tetrafluoroethane (TFE-134), also forms a single-phase, homogeneous mixture with photoresist compositions and is a non-ozone-depleting propellant. TFE-134 propellant is miscible with negative and positive photoresist compositions containing 1-methoxy-2-propanol, 1-methoxy-2-propanol acetate, ethyl lactate or cyclopentanone and is a liquid under pressure.

The relative percentages of the photoresist composition and propellant may vary over any ratio, as long as a suitable ballistic aerosol spray capable of forming a uniform coating on a substrate can be made. Preferably, this ratio may be from about 80% to about 95% by weight photoresist composition to about 20% to 5% by weight propellant.

A preferred positive photoresist composition contains: 50-90% by weight of 1-methoxy-2-propanol ether acetate, 2-50% by weight of novolak resin, and 1-10% ortho-quinone-diazide photo-sensitizer.

A preferred negative photoresist composition contains: 50-90% by weight of 1-methoxy-2-propanol ether acetate, 2-50% by weight of novolak resin, 2-25% by weight of glycouril cross-linking compound and 5-15% by weight cationic photo-initiators.

A preferred aspect of the self-cross-linking negative photoresist composition solution contains 50-90% by weight of solvents, preferably propylene glycol monomethyl ether acetate, 2-50% by weight of Epon resin and 5-15% by weight cationic photoinitiators.

The mixtures may be prepared by any suitable means. Preferably, the photoresist composition is prepared first which is transferred to a pressurized container and sealed with the release valve in place. Once the seal is complete, the vessel is pressurized with the propellant gas or gas mixture through the valve to create a pressurized environment within that container.

Alternatively, propellants which do not form a single-phase pressurized aerosol mixture with the photoresist composition, but which do change physical state to become or which produce a gas once released at standard pressure may be used in a ballistic aerosol spray. In this alternative embodiment, the mixture may be transferred into a vessel with an internal bladder, diaphragm, bag, piston, or other flexible pressurizing means, and sealed with the release valve in place. Once the seal is complete, the vessel is pressurized through a separate inlet other than the release valve, such as through the bottom of the vessel, and sealed with a permanent rubber seal. Such a vessel, known as two-component or hybrid construction, eliminates the need for the propellant and photoresist to be miscible.

The pressurized container may be any suitable container capable of releasing a ballistic aerosol spray. The container is preferably a can that has a release valve, a delivery tube within the can, and an actuator or nozzle. The selection of these elements are not critical to producing a uniform coating and a stable aerosol propellant composition. Any can element may be used as long as a ballistic, aerosol spray is emitted from the can such that the lining of the can does not react with the composition, is stable with time, and produces a uniform bubble-free coating. The pressurized container may be lined with an epoxy or Tin (Sn) coating or some other coating suitable for preventing a chemical reaction of the composition with the interior of the container.

The pressures contained in the container are generally greater than 1 atm pressure, and more preferably range from 20 to 100 PSI, and most preferably from 40 to 60 PSI. One preferred pressure is about 50 PSI.

The ballistic aerosol spray is applied to a substrate in an amount that is preferably for that particular end use. Generally, the applied coating will produce a dried film thickness of from 1 to 100 microns thick.

The substrate material to which the aerosol spray may be applied may be any shape of conventional substrate to which photoresist compositions are normally applied. Suitable substrates include, but are not limited to, silicon, silicon dioxide, silicon nitride, alumina, glass, quartz, fused silica, ceramics, glass-ceramics, gallium arsenide, indium phosphide, copper, aluminum, nickel, iron, steel, stainless steel, tin, copper-silicon alloys, indium-tin oxide coated class, organic films such as polyimide and polyester, as well as dry film layers previously imaged, including dry film layers of the present invention, and any substrate bearing patterned areas of metal, semiconductor and insulating materials and the like. No special pre-treatment of the substrate is necessary for operation of the invention however the positive photoresist composition may benefit from a pretreatment of hydroxymethyl disilazane (HMDS). Optionally, a bake step may be performed on the substrate to remove absorbed moisture from the substrate prior to applying the photoresist coating.

The applied coatings of the present invention may be used to make a wide variety of articles that are useful for the fabrication of electronic components, micro-electromechanical system (MEMS) components, micromachine components, microfluidic components, bioMEMS components, micro total analysis system (μ-TAS) components, medical devices, micro optical or waveguide components, microreactor components, electroconductive layers, lithographie galvanoformung abformung (LIGA) components, displays, forms and stamps for microinjection molding and microembossing, screens or stencils for fine printing applications, MEMS and IC packaging (passivation or stress/buffer coats, die attach and no-flow underfills, and the like), wafer level packaging (wafer bonding, chip stacking, 3-D interconnects and the like), integrated passives and printed wiring boards (high density interconnects, solder masks, inner layers, and the like) that can be processed by ultraviolet (UV), visible light, infra-red radiation, x-ray or electron beam lithography. Suitable electronic component applications include metallization layers, dielectric layers, insulation layers, etch resistant layers, wafer bonding layers and semiconductor circuits. Optical applications include, optical interconnects, waveguides, optical switches, spacers, optical displays, flexible OLEDs, backplanes, diffuser or reflector elements or protective coatings for optical, LED or OLED components. Other uses include as resin or polymer substrates for other photoimageable layers or as films for UV or hot embossing of patterned structures such as for nano-imprint lithography or large area display applications and in the construction of structures for the separation, analysis, and preparation of arrays for biochemical analysis and in the construction of cell growth platforms for biological materials. Still other suitable applications may include the use as cover sheets in the fabrication of buried channel and air-bridge structures used, for example, in microfluidic or optical devices or for the reservoir, fluidic channels or nozzle layer of ink jet heads.

### EXAMPLES

The present invention is further described in detail by means of the following Examples and Comparisons. All parts and percentages are by weight and all temperatures are degrees Celsius unless explicitly stated otherwise.

### Example 1

A negative-acting, photoresist aerosol spray formulation was prepared by combining 49.42 grams of Rezicure 5200 novolak resin (Schenectady International, Schenectady, N.Y.), 49.42 grams of Rezicure 5300 (Schenectady International, Schenectady, N.Y.), 22.55 grams of tetramethoxymethyl glycoluril (available from Cytec Industries, Inc., West Paterson, N.J. as Powderlink 1174), 0.12 grams of OHBAB dye, 0.97 grams of Fluor N 562 (Cytonix Corporation, Beltsville, Md.), 12.97 grams of a mixture of a mixture of triarylsulfonium hexafluoroantimonate salts in propylene carbonate (available from Dow Chemical Corporation, Midland, Mich. as UVI-6976) and 302.09 grams of 1-methoxy-2-propanol acetate into a uniform homogeneous mixture. Thereafter, 437.54 grams of the mixture were decanted into a three-piece, tin-lined, steel aerosol can (United States Can Company, Oak Brook, Ill.) and sealed with a valve consisting of butyl rubber and a Teflon (PTFE) dip tube (Newman-Green, Addison, Ill.). To this mixture, 35.57 grams of dimethyl ether was injected through the valve and into the can to a pressure of 50 psi. The can was shaken lightly and delivered through a flat-fan spray nozzle (Newman-Green, Addison, Ill.) onto a polished silicon wafer surface. Nine overlapping spray passes were used to produce a uniform coating, which was left to sit for 5 minutes at room temperature, followed by placing the coated substrate on a 95° C. hot plate for 5 minutes to dry the coating. The coating thickness uniformity was measured using a FilmTek film thickness gauge and found to be 10 microns ±0.5 micron across a 150 mm wafer.

### Example 2

A negative-acting photoresist aerosol spray formulation using a self-crosslinking polymer was prepared by combining 381.76 grams of Epon Resin SU-8 (available from Hexion Specialty Chemicals, Inc.), 3.04 grams of Fluor N 562 Surfactant (available from Cytonix Corporation), 38.10 grams of a mixture of a mixture of triarylsulfonium hexafluoroantimonate salts in propylene carbonate (available from Dow Chemical Corporation as UVI-6976) and 577.15 grams of 1-methoxy-2-propanol acetate into a uniform homogeneous mixture. Thereafter, 437.54 grams of the mixture were decanted into a three-piece, tin-lined, steel aerosol can (available from United States Can Company) and sealed with a valve consisting of butyl rubber and a Teflon (PTFE) dip tube. To this mixture, 35.57 grams of dimethyl ether was injected through the valve and into the can to a pressure of 50 psi. The can was shaken lightly and delivered through a flat-fan spray nozzle onto a polished silicon wafer surface. Nine overlapping spray passes were used to produce a uniform coating, which was left to sit for 5 minutes at room temperature, followed by placing the coated substrate on a 95° C. hot plate for 5 minutes to dry the coating. The coating thickness uniformity was measured using a FilmTek film thickness gauge and found to be 10 microns ±0.5 micron across a 150 mm wafer.

### Example 3

Another negative-acting photoresist aerosol spray formulation using a self-crosslinking polymer was prepared by combining 381.76 grams of Epon Resin SU-8 (available from Hexion Specialty Chemicals, Inc.), 3.04 grams of Fluor N 562 Surfactant (available from Cytonix Corporation), 38.10 grams of a mixture of a mixture of triarylsulfonium hexafluoroantimonate salts in propylene carbonate (available from Dow Chemical Corporation as UVI-6976) and 577.15 grams of 1-methoxy-2-propanol acetate into a uniform homogeneous mixture. Thereafter, 437.54 grams of the mixture were decanted into a three-piece, tin-lined, steel aerosol can (available from United States Can Company) and sealed with a valve consisting of butyl rubber and a Teflon (PTFE) dip tube. To this mixture, 35.57 grams of 1,1,1,2-tetrafluoroethane (available from DuPont Corporation as FC 134a), was injected through the valve and into the can to a pressure of 50 psi. The can was shaken lightly and delivered through a flat-fan spray nozzle onto a polished silicon wafer surface. Nine overlapping spray passes were used to produce a uniform coating, which was left to sit for 5 minutes at room temperature, followed by placing the coated substrate on a 95° C. hot plate for 5 minutes to dry the coating. The coating thickness uniformity was measured using a FilmTek film thickness gauge and found to be 10 microns ±0.5 micron across a 150 mm wafer.

### Example 4

A positive-acting, photoresist aerosol spray formulation consisting of novolak resins, diazonaphthoquinone sulfonate, fluoroaliphatic polymer esters and 1-methoxy-2-propanol acetate (available as S1813 from Rohm & Haas Electronic Materials Co.) was prepared by decanting 437.54 grams into a three-piece, tin-lined, steel aerosol can (available from United States Can Company) and sealed with a valve consisting of butyl rubber and a Teflon (PTFE) dip tube. To this mixture, 35.57 grams of 1,1,1,2-tetrafluoroethane (available from DuPont Corporation as FC 134a), was injected through the valve and into the can to a pressure of 50 psi. The can was shaken lightly and delivered through a flat-fan spray nozzle onto a polished silicon wafer surface. Nine overlapping spray passes were used to produce a uniform coating, which was left to sit for 5 minutes at room temperature, followed by placing the coated substrate on a 95° C. hot plate for 5 minutes to dry the coating. The coating thickness uniformity was measured using a FilmTek film thickness gauge and found to be 10 microns ±0.5 micron across a 150 mm wafer.

### Example 5

A positive-acting, photoresist aerosol spray formulation consisting of novolak resins, diazonaphthoquinone sulfonate, fluoroaliphatic polymer esters and 1-methoxy-2-propanol acetate (available as S1813 from Rohm & Haas Electronic Materials Co.) was prepared by decanting 437.54 grams into a three-piece, tin-lined, steel aerosol can (available from United States Can Company) and sealed with a valve consisting of butyl rubber and a Teflon (PTFE) dip tube. To this mixture, 35.57 grams of dimethyl ether, was injected through the valve and into the can to a pressure of 50 psi. The can was shaken lightly and delivered through a flat-fan spray nozzle onto a polished silicon wafer surface. Nine overlapping spray passes were used to produce a uniform coating, which was left to sit for 5 minutes at room temperature, followed by placing the coated substrate on a 95° C. hot plate for 5 minutes to dry the coating. The coating thickness uniformity was measured using a FilmTek film thickness gauge and found to be 10 microns ±0.5 micron across a 150 mm wafer.

### Example 6

A positive-acting, lift-off photoresist formulation consisting of 104.15 grams of polydimethyl-glutarimide (available as PMGI or LOR from MicroChem Corp. of Newton, Mass.), 0.81 grams of OHBAB dye and 887.81 grams of a solvent mixture blend was prepared by decanting 437.54 grams of the photoresist mixture into a three-piece, tin-lined, steel aerosol can (available from United States Can Company) and sealed with a valve consisting of butyl rubber and a Teflon (PTFE) dip tube. To this mixture, 35.57 grams of 1,1,1,2-tetrafluoroethane (available from DuPont Corporation as FC 134a), was injected through the valve and into the can to a pressure of 50 psi. The can was shaken lightly and delivered through a flat-fan spray nozzle onto a polished silicon wafer surface. Nine overlapping spray passes were used to produce a uniform coating, which was left to sit for 5 minutes at room temperature, followed by placing the coated substrate on a 95° C. hot plate for 5 minutes to dry the coating. The coating thickness uniformity was measured using a FilmTek film thickness gauge and found to be 10 microns ±0.5 micron across a 150 mm wafer.

### Example 7

A positive-acting, lift-off photoresist formulation consisting of 104.15 grams of polydimethyl-glutarimide (available as PMGI or LOR™ from MicroChem Corp. of Newton, Mass.), 0.81 grams of OHBAB dye and 887.81 grams of a solvent mixture blend was prepared by decanting 437.54 grams of the photoresist mixture into a three-piece, tin-lined, steel aerosol can (available from United States Can Company) and sealed with a valve consisting of butyl rubber and a Teflon (PTFE) dip tube. To this mixture, 35.57 grams of dimethyl ether, was injected through the valve and into the can to a pressure of 50 psi. The can was shaken lightly and delivered through a flat-fan spray nozzle onto a polished silicon wafer surface. Nine overlapping spray passes were used to produce a uniform coating, which was left to sit for 5 minutes at room temperature, followed by placing the coated substrate on a 95° C. hot plate for 5 minutes to dry the coating. The coating thickness uniformity was measured using a FilmTek film thickness gauge and found to be 10 microns ±0.5 micron across a 150 mm wafer.

While the invention has been described above with reference to specific embodiments thereof, it is apparent that many changes, modifications, and variations can be made without departing from the inventive concept disclosed herein. Accordingly, it is intended to embrace all such changes, modifications, and variations that fall within the spirit and broad scope of the appended claims. All patent applications, patents and other publications cited herein are incorporated by reference in their entirety.

What is claimed is:

1. A coating composition, comprising:
a photoresist composition; and
a propellant miscible in said photoresist composition.

2. The coating composition of claim 1, wherein said photoresist is negative-acting.

3. The coating composition of claim 2, wherein said negative-acting photoresist composition comprises a polymer component comprising at least one novolak resin and a glycouril crosslinking compound.

4. The coating composition of claim 2, wherein said negative-acting photoresist composition comprises a polymer component comprising bisphenol A.

5. The coating composition of claim 2, wherein said negative-acting photoresist composition comprises a photosensitive component comprising a hexafluoroantimonate salt.

6. The coating composition of claim 2, wherein said negative-acting photoresist composition comprises a solvent selected from the group consisting of cyclopentanone, propylene glycol monomethyl ether acetate, ethyl lactate, acetone, 1-methoxy-2-propanol, 1-methoxy-2-propanol acetate, and combinations thereof.

7. The coating composition of claim 2, wherein said negative-acting photoresist composition comprises additional ingredients selected from the group consisting of surfactants, plasticizers, dyes, photoinitiators, and combinations thereof.

8. The coating composition of claim 2, wherein said propellant is a hydrocarbon propellant selected from the group consisting of dimethoxymethane, ethyl acetone, acetone, dimethyl ether, 2-methoxyethanol, 2-ethoxyethanol, butanol, 1,1,1,2-tetrafluoroethane, and combinations thereof.

9. The coating composition of claim 2, wherein said the amount of said negative-acting photoresist in said coating composition ranges from about 80 wt % to about 95 wt %, based on the total weight of said coating composition.

10. The coating composition of claim 2, wherein said the amount of said propellant in said coating composition ranges from about 5 wt % to about 20 wt %, based on the total weight of said coating composition.

11. The coating composition of claim 2, wherein said negative-acting photoresist composition comprises 2-50 wt % of novolak resin; 2-25 wt % of a glycouril crosslinking compound; 50-90 wt % of 1-methoxy-2-propanol ether acetate solvent; and 5-15 wt % of cationic photoinitiators, all based on the total weight of said negative-acting photoresist composition.

12. The coating composition of claim 2, wherein said negative-acting photoresist composition comprises 2-50 wt % of a polymer component comprising bisphenol A; 5-15 wt % of of cationic photoinitiators; and 50-90 wt % of 1-methoxy-2-propanol ether acetate solvent, all based on the total weight of said negative-acting photoresist composition.

13. A pressurized container, comprising:
a coating composition contained in said pressurized container and comprising:
a photoresist composition; and
a propellant miscible in said photoresist composition; and
a valve capable of forming an aerosol spray of said coating composition when activated;
wherein said pressurized container has a pressure of greater than 1 atm.

14. The pressurized container of claim 13, wherein said photoresist is negative-acting.

15. The pressurized container of claim 13, wherein said negative-acting photoresist composition comprises a polymer component comprising at least one novolak resin and a glycouril crosslinking compound.

16. The pressurized container of claim 13, wherein said negative-acting photoresist composition comprises a polymer component comprising bisphenol A.

17. The pressurized container of claim 13, wherein said negative-acting photoresist composition comprises a photosensitive component comprising a hexafluoroantimonate salt.

18. The pressurized container of claim 13, wherein said negative-acting photoresist composition comprises a solvent selected from the group consisting of cyclopentanone, propylene glycol monomethyl ether acetate, ethyl lactate, acetone, 1-methoxy-2-propanol, 1-methoxy-2-propanol acetate, and combinations thereof.

19. The pressurized container of claim 13, wherein said negative-acting photoresist composition comprises additional ingredients selected from the group consisting of surfactants, plasticizers, dyes, photoinitiators, and combinations thereof.

20. The pressurized container of claim 13, wherein said propellant is selected from the group consisting of dimethoxymethane, ethyl acetone, acetone, dimethyl ether, 2-methoxyethanol, 2-ethoxyethanol, butanol, 1,1,1,2-tetrafluoroethane, nitrogen (N₂), carbon dioxide (CO₂), and combinations and azeotropes thereof.

21. The pressurized container of claim 13, wherein said the amount of said negative-acting photoresist in said coating composition ranges from about 80 wt % to about 95 wt %, based on the total weight of said coating composition.

22. The pressurized container of claim 13, wherein said the amount of said propellant in said coating composition ranges from about 5 wt % to about 20 wt %, based on the total weight of said coating composition.

23. The pressurized container of claim 13, wherein said negative-acting photoresist composition comprises 2-50 wt % of novolak resin; 2-25 wt % of a glycouril crosslinking compound; 50-90 wt % of 1-methoxy-2-propanol ether acetate solvent; and 5-15 wt % of cationic photoinitiators, all based on the total weight of said negative-acting photoresist composition.

24. The pressurized container of claim 13, wherein said negative-acting photoresist composition comprises 2-50 wt % of a polymer component comprising bisphenol A; 5-15 wt % of of cationic photoinitiators; and 50-90 wt % of 1-methoxy-2-propanol ether acetate solvent, all based on the total weight of said negative-acting photoresist composition.

25. The pressurized container of claim 13, wherein the pressure inside said container ranges from 20 PSI to 100 PSI.

26. A pressurized container, comprising:
a first chamber comprising a a valve capable of forming an aerosol spray and containing a coating composition comprising a photoresist composition; and
a second chamber adjacent to said first chamber and applying pressure to said first chamber.

27. The pressurized container of claim 26, wherein said photoresist is negative acting.

28. The pressurized container of claim 27, wherein said negative-acting photoresist composition comprises a polymer component comprising at least one novolak resin and a glycouril crosslinking compound.

29. The pressurized container of claim 27, wherein said negative-acting photoresist composition comprises a polymer component comprising bisphenol A.

30. The pressurized container of claim 27, wherein said negative-acting photoresist composition comprises a photosensitive component comprising a hexafluoroantimonate salt.

31. The pressurized container of claim 27, wherein said negative-acting photoresist composition comprises a solvent selected from the group consisting of cyclopentanone, propylene glycol monomethyl ether acetate, ethyl lactate, acetone, 1-methoxy-2-propanol, 1-methoxy-2-propanol acetate, and combinations thereof.

32. The pressurized container of claim 27, wherein said negative-acting photoresist composition comprises additional ingredients selected from the group consisting of surfactants, plasticizers, dyes, photoinitiators, and combinations thereof.

33. The pressurized container of claim 27, wherein said negative-acting photoresist composition comprises 2-50 wt % of novolak resin; 2-25 wt % of a glycouril crosslinking compound; 50-90 wt % of 1-methoxy-2-propanol ether acetate solvent; and 5-15 wt % of cationic photoinitiators, all based on the total weight of said negative-acting photoresist composition.

34. The pressurized container of claim 27, wherein said negative-acting photoresist composition comprises 2-50 wt % of a polymer component comprising bisphenol A; 5-15 wt % of of cationic photoinitiators; and 50-90 wt % of 1-methoxy-2-propanol ether acetate solvent, all based on the total weight of said negative-acting photoresist composition.

35. The pressurized container of claim 27, wherein the pressure inside said second chamber ranges from about 20 to about 100 PSI.

36. The pressurized container of claim 27, wherein said second chamber comprises compressed gasses selected from the group consisting of nitrogen gas, carbon dioxide gas, and combinations thereof.

37. The pressurized container of claim 27, wherein said second chamber is selected from a bladder, diaphragm, bag, or piston.
